(19) United States
(12) Patent Application Publication
(10) Pub. No.: US 2012/0234593 A1
(43) Pub. Date: Sep. 20, 2012

(54) CONDUCTIVE FOILS HAVING MULTIPLE LAYERS AND METHODS OF FORMING SAME

(75) Inventors: William BOTTENBERG, Boulder Creek, CA (US); John Telle, Albuquerque, NM (US); David H. Meakin, Albuquerque, NM (US); Brian J. Murphy, Albuquerque, NM (US)

(73) Assignee: APPLIED MATERIALS, INC., Santa Clara, CA (US)

(21) Appl. No.: 13/420,453

(22) Filed: Mar. 14, 2012

Related U.S. Application Data
(60) Provisional application No. 61/487,599, filed on May 18, 2011.
(60) Provisional application No. 61/454,382, filed on Mar. 18, 2011.

(51) Int. Cl. H05K 1/09; C23C 14/34

(52) U.S. Cl. 174/268; 204/192.1

(57) ABSTRACT

Embodiments of the invention generally relate to conductive foils having multiple layers for use in photovoltaic modules and methods of forming the same. The conductive foils generally include a layer of aluminum foil having one or more metal layers with decreased contact resistance disposed thereon. An anti-corrosion material and a dielectric material are generally disposed on the upper surface of the metal layer. The conductive foils may be formed on a carrier prior to construction of a photovoltaic module, and then applied to the photovoltaic module as a conductive foil assembly during construction of the photovoltaic module. Methods of forming the conductive foils generally include adhering an aluminum foil to a carrier, removing native oxides from a surface of the aluminum foil, and sputtering a metal onto the aluminum foil. A dielectric material and an anti-corrosion material may then be applied to the upper surface of the sputtered metal.

### CROSS-REFERENCE TO RELATED APPLICATIONS

This application claims benefit of U.S. provisional patent application Ser. No. 61/487,599 [Atty. Dkt. No. APPM/16284L], filed May 18, 2011, and U.S. Provisional Patent Application Ser. No. 61/454,382 [Atty. Dkt. No. APPM/16122L], filed Mar. 18, 2011, which are both herein incorporated by reference.

### BACKGROUND OF THE INVENTION

1. Field of the Invention

Embodiments of the invention generally relate to conductive foils used in the manufacture of photovoltaic modules having back-contact cells and methods of producing the same.

2. Description of the Related Art

Solar cells are photovoltaic devices that convert sunlight into electrical power. Each solar cell generates a specific amount of electric power and is typically tiled into an array of interconnected solar cells that are sized to deliver a desired amount of generated electrical power. The generated electrical power is transported from the solar cells to a junction box by a conductive circuit coupled to the rear contacts of the solar cells. The conductive circuit is usually formed from copper, which is a relatively expensive material, and thus represents a sizeable portion of the total cost of the manufactured array. The increased production cost of the array results in an increased cost per kilowatt hour produced by the array.

Therefore, there is a need for lower cost conductive foils for photovoltaic modules and methods of producing the same.

### SUMMARY OF THE INVENTION

Embodiments of the invention generally relate to conductive foils having multiple layers for use in photovoltaic modules and methods of forming the same. The conductive foils generally include a layer of aluminum foil having one or more metal layers with decreased contact resistance disposed thereon. An anti-corrosion material and a dielectric material are generally disposed on the upper surface of the metal layer. The conductive foils may be formed on a carrier prior to construction of a photovoltaic module, and then applied to the photovoltaic module as a conductive foil assembly during construction of the photovoltaic module. Methods of forming the conductive foils generally include adhering an aluminum foil to a carrier, removing native oxides from a surface of the aluminum foil, and sputtering a metal onto the aluminum foil. A dielectric material and an anti-corrosion material may then be applied to the upper surface of the sputtered metal.

In one embodiment, a conductive foil assembly comprises a carrier comprising polyester, an adhesive disposed on one surface of the carrier, and a conductive foil disposed on the adhesive. The conductive foil comprises an aluminum foil in contact with the adhesive, a copper layer disposed over the aluminum foil, and an anti-corrosion material disposed on the copper layer.

In another embodiment, a conductive foil assembly comprises a carrier and an adhesive disposed on one surface of the carrier. A conductive foil is disposed on the adhesive. The conductive foil comprises an aluminum foil in contact with the adhesive, a first metal layer disposed over the aluminum foil, and an anti-corrosion material disposed on the first metal layer.

In another embodiment, a method of forming a conductive foil assembly comprises adhering an aluminum foil to a carrier. The aluminum foil and the carrier are then positioned in a sputtering chamber and supported on a feed roller and a take-up roller. A surface of the aluminum foil is exposed to an ionized gas to remove native oxides therefrom, and then a metal is sputtered over the surface of the aluminum foil. A dielectric material having openings therethrough is applied onto a surface of the sputtered metal, and then an anti-corrosion material is applied to the sputtered metal in the areas defined by the openings through the dielectric material.

In another embodiment, a photovoltaic module comprises a first carrier and a conductive foil assembly adhered to a surface of the first carrier. The conductive foil assembly comprises a second carrier and an aluminum foil adhered to the second carrier. A first metal layer is disposed over the aluminum foil, and an anti-corrosion material is disposed on the first metal layer. A dielectric material having openings therethrough is disposed over the first metal layer. The photovoltaic module also includes an encapsulant material disposed over the dielectric material. The encapsulant material has openings therethrough positioned adjacent to the openings through the dielectric material. A conductive adhesive is disposed within the openings through the dielectric material and the openings through the encapsulant material. The conductive adhesive is in electrical contact with the first metal layer. A plurality of solar cells are positioned over the encapsulant material and in contact with the conductive adhesive. The plurality of solar cells are electrically coupled to the first metal layer through the conductive adhesive.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a top plan view of a partial cross-sectional of a photovoltaic module according to one embodiment of the invention.

FIG. 2 is a sectional view of the photovoltaic module of FIG. 1 along section line 2-2.

FIG. 3A is a top plan view of a conductive foil assembly according to one embodiment of the invention.

FIG. 3B is a cross-sectional view of the conductive foil assembly shown in FIG. 3A along section line 3B-3B.

FIG. 4 is a flow diagram illustrating a method for forming a photovoltaic module according to one embodiment of the invention.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the invention generally relate to conductive foils having multiple layers for use in photovoltaic modules and methods of forming the same. The conductive foils generally include a layer of aluminum foil having one or more metal layers with decreased contact resistance disposed thereon. An anti-corrosion material and a dielectric material are generally disposed on the upper surface of the metal layer. The conductive foils may be formed on a carrier prior to construction of a photovoltaic module, and then applied to the photovoltaic module as a conductive foil assembly during construction of the photovoltaic module. Methods of forming the conductive foils generally include adhering an aluminum foil to a carrier, removing native oxides from a surface of the aluminum foil, and sputtering a metal onto the aluminum foil. A dielectric material and an anti-corrosion material may then be applied to the upper surface of the sputtered metal.

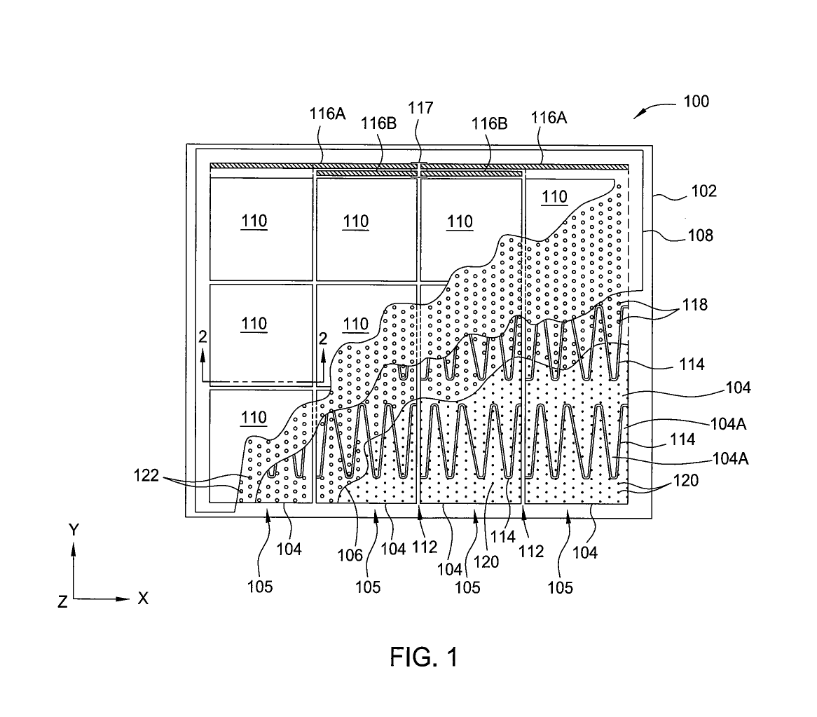

FIG. 1 is a top plan view of a partial cross-section of a photovoltaic module 100 according to one embodiment of the invention. The photovoltaic module 100 is viewed from the light-receiving side of the photovoltaic module 100, and is shown as having layers thereof removed in a top-to-bottom manner to illustrate components of the photovoltaic module 100. The photovoltaic module 100 illustrates an array of interconnected solar cells 110 disposed over the top surface of a carrier 102. The photovoltaic module 100 includes a carrier 102, a plurality of conductive foils 104, a dielectric material 106, an encapsulant material 108, and a plurality of solar cells 110. The carrier 102 includes a top sheet of polymeric material, such as polyester, polyvinyl fluoride, polyethelene terephthalate, polyethelene naphthalate, MYLAR®, KAPTON® or TEDLAR® adhered to a bottom sheet of aluminum. The polymeric material generally has a thickness within a range from about 100 microns to about 200 microns, while the aluminum layer generally has a thickness of about 9 microns to about 50 microns. The aluminum layer of the carrier 102 is positioned on the back surface of the photovoltaic module 100 to act as a moisture and vapor barrier.

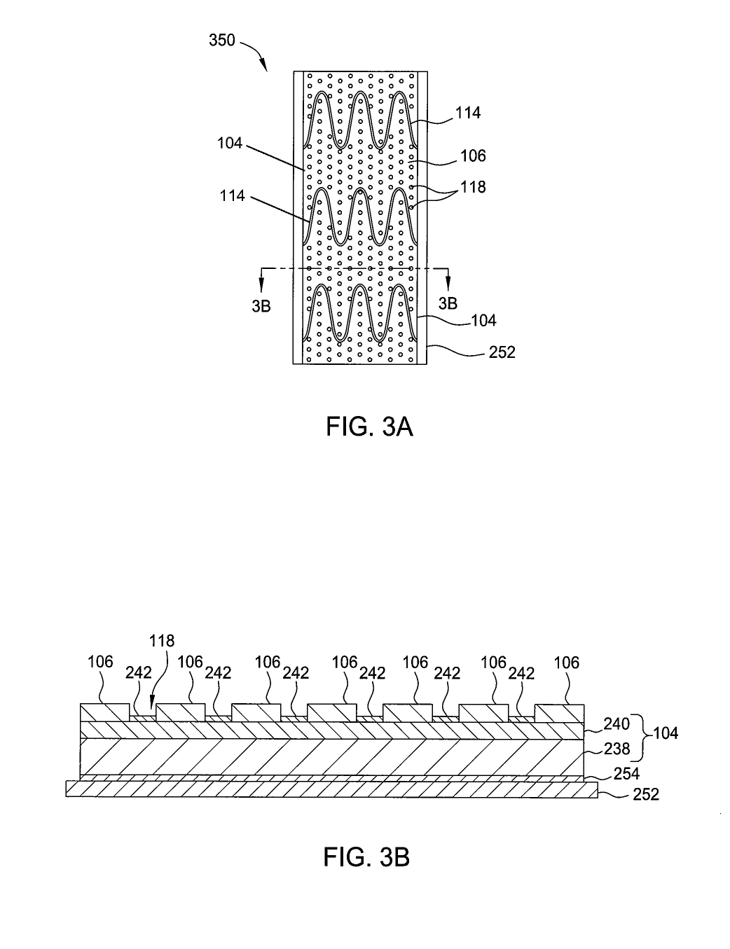

A plurality of conductive foils 104 are positioned on the front surface of the carrier 102 and adhered to the polymeric material of the carrier 102. The conductive foils 104 are flexible conductive strips of metal sized to have a desired number of solar cells 110 electrically coupled thereto. The conductive foils 104 are generally patterned conductive foils having a predetermined shape, configuration, or circuit pattern formed therein. The conductive foils 104 shown in FIG. 1 are each sized to have three solar cells 110, such as back contact solar cells, coupled thereto. However, it is contemplated that the size of each conductive foil 104 may be adjusted to accommodate more than three solar cells 110. The conductive foils 104 are spaced apart from one another by gaps 112 to provide electrical isolation therebetween. Each of the conductive foils 104 includes a plurality of grooves 114 formed therein to physically and electrically separate portions of each conductive foil 104. In some configurations, as illustrated in FIG. 1, the carrier 102 may have a plurality of columnar strips 105 that are disposed and/or adhered thereon. The columnar strips 105 generally comprise a plurality of conductive foils 104, or conductive regions, that are separated from each other in one direction (e.g., Y-direction) by the grooves 114 and separated from other columnar strips 105 in another direction (e.g., X-direction) by the gaps 112. In one configuration, each of the grooves 114 that separates the conductive foils 104 in a columnar strip 105 are formed in an interleaving pattern, wherein the grooves 114, or separation grooves, are non-straight, non-linear and/or have a wavy pattern, as illustrated in FIGS. 1 and 3. Thus, each of the adjacently positioned conductive foils 104 may have finger regions 104A that are physically and electrically separated from each other by the groove 114. The separation groove 114 may be formed by removing portions of a solid conductive foil material, for example, by use of an automated punch press, abrasive saw, laser scribing device or other similar cutting technique. In one configuration, each of the conductive foils 104 is formed in a separate formation process and then positioned in a spaced apart relationship on the carrier 102 so that the groove 114 electrically separates each conductive foil 104.

Each of the solar cells 110 is positioned over one of the grooves 114 and placed in electrical contact with the finger regions 104A of the conductive foils 104. A back contact of the solar cell 110 having a first electrical polarity (e.g., n-type regions) is positioned in electrical contact with the finger regions 104A of the conductive foil 104 on one side of the groove 114, while a back contact of the same solar cell 110 having an opposite electrical polarity (e.g., p-type regions) is positioned in electrical contact with the finger regions 104A of the conductive foil 104 on the opposite side of the groove 114. Thus, when used in a photovoltaic module that has a plurality of solar cells that are connected in series, the finger regions 104A of the conductive foils 104 are used to connect regions formed in adjacent solar cells that have opposing dopant types. In one example, each columnar strip 105, containing conductive foils 104, is used to interconnect a group of solar cells 110 in series, such as the four solar cells 110 disposed in one of the four solar cell columns over the columnar strips 105 in the photovoltaic module 100. The solar cells 110 disposed in the photovoltaic module 100 may be formed from substrates containing materials such as single crystal silicon, multi-crystalline silicon, polycrystalline silicon, germanium (Ge), gallium arsenide (GaAs), cadmium telluride (CdTe), cadmium sulfide (CdS), copper indium gallium selenide (CIGS), copper indium selenide (CuInSe₂), gallium indium phosphide (GaInP₂), as well as heterojunction cells, such as GaInP/GaAs/Ge, ZnSe/GaAs/Ge or other similar substrate materials that are used to convert sunlight to electrical power. Electric current generated by each of the solar cells 110 travels through the solar cells 110 and the conductive foil 104 coupled thereto via a series connection to busbars 116A, 116B. Current is then extracted from the photovoltaic module 100 through the busbars 116A, 116B which are connected to a junction box (not shown) through opening 117 disposed through the carrier 102. It should be noted that the conductive foils 104 positioned near the edges of the photovoltaic module 100 have length greater than the conductive foils 104 positioned interior thereto. The conductive foils 104 positioned near the edges have a greater length in order to contact the busbars 116A which are positioned further away from the conductive foils 104 than the busbars 116B (which are in contact with the conductive foils 104 positioned near the interior of the photovoltaic module 100). In some configurations, as illustrated in FIG. 1, at least two of the columnar strips 105 of conductive foils 104 have an uneven-length in one or more directions across a surface of the carrier 102 (e.g., X-Y plane). In one example, as shown in FIG. 1, the outermost columnar strips 105 are longer in the Y-direction than the middle two columnar strips 105. As noted above, this configuration of the columnar strips 105 will allow the busbars 116A, which are electrically coupled to the outermost columnar strips 105, to carry current to the junction box opening 117 without contacting the other columnar strips 105 (e.g., middle columnar strips 105), and the busbars 116B, which are electrically coupled to the inner-columnar strips 105, to carry current to the junction box opening 117 without contacting the busbars 116A.

A dielectric material 106, such as an acrylate or methacrylate, is disposed over the upper surface of each the conductive foils 104. The dielectric material 106 is not disposed in the gaps 112, the grooves 114, or on the upper surface of the carrier 102 as shown in FIG. 1. It is contemplated, however, that the dielectric material 106 may be disposed in the gaps 112 or the grooves 114 in some embodiments. The dielectric material 106 provides electrical isolation in desired locations between the conductive foils 104 and the solar cells 110 positioned thereon. The dielectric material 106 includes a plurality of openings 118 formed therethrough to allow a conductive adhesive 120 to be disposed therein. The conductive adhesive 120 may be a metal containing paste, and is positioned to form an electrical connection between the back contacts of the solar cells 110 and the conductive foils 104. An anti-corrosion material (not shown), is disposed under the conductive adhesive 120 on the upper surface of the conductive foil 104. The anti-corrosion material, which may be an organic solderability preservative (OSP) material, such as an organic triazole, prevents tarnishing, corrosion, or oxidation of the upper surface of the conductive foil 104 to allow a stable bond to be formed thereto.

An encapsulant material 108, such as ethylene-vinyl acetate (EVA), is disposed over the dielectric material 106. The encapsulant material 108 serves to occupy spaces within the photovoltaic module 100 to prevent gaps where moisture may collect; the occurrence of which would undesirably degrade the reliability of the photovoltaic module 100. The encapsulant material 108 includes openings 122 formed therethrough. The openings 122 formed through the encapsulant material 108 are aligned with the openings 118 formed through dielectric material 106. The alignment of openings 118 and 122 allows the conductive adhesive 120 to contact the solar cells 110 that are positioned on the upper surface of the encapsulant material 108.

While the photovoltaic module 100 of FIG. 1 includes four conductive foils 104, it is contemplated that any number of conductive foils may be applied to the surface of the carrier 102. It is contemplated that the number of conductive foils 104, or the number of solar cells 110 coupled to each conductive foil 104 can be adjusted depending on the desired number of solar cells 110 to be included in the photovoltaic module 100. In one example, a photovoltaic module having a length of 1.7 meters and width of 1 meter includes six conductive foils each having a width of about 16 centimeters and a length of about 1.6 meters.

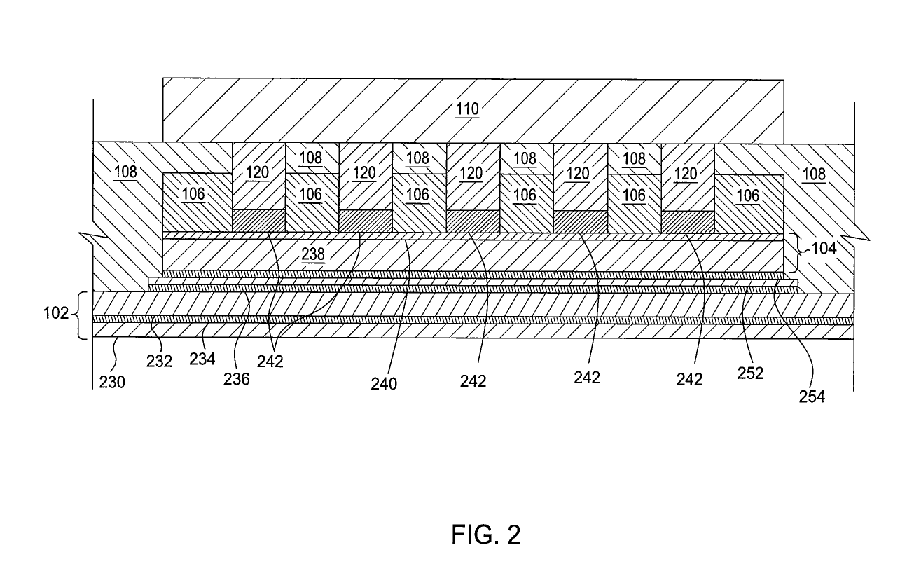

FIG. 2 is a sectional view of the photovoltaic module 100 of FIG. 1 along section line 2-2. FIG. 2 illustrates a solar cell 110 positioned on an encapsulant material 108 and electrically connected to a conductive foil 104 by a conductive adhesive 120. The conductive foil 104 is positioned on and supported by a carrier 102. The carrier 102 includes an aluminum layer 230 adhered to a polymeric material 232 by an adhesive 234, such as a pressure sensitive adhesive. The conductive foil 104 is adhered to a carrier 252 by an adhesive 254. The carrier 252, which may be formed from a polymeric material, supports the conductive foil 104 prior to integration of the conductive foil 104 into the photovoltaic module. The carrier 252 is adhered to the upper surface of the carrier 102 by an adhesive 236, such as a pressure sensitive adhesive.

The conductive foil 104 includes multiple conductive layers formed from at least two different metals. The conductive foil 104 includes a layer of aluminum foil 238 and a metal layer 240, such as copper, disposed on the upper surface of the aluminum foil 238. The aluminum foil 238 is formed from 1145 aluminum (Aluminum Association designation) and has a thickness within a range from about 25 microns to about 100 microns, for example, about 75 microns. The metal layer 240 generally has a thickness less than the thickness of the aluminum foil 238. For example, when the metal layer 240 is copper, the metal layer 240 may have a thickness within a range from about 500 angstroms to about 2500 angstroms, such as about 1000 angstroms. The metal layer 240 is disposed on the aluminum foil 238 to reduce the contact resistance of electrically conductive materials disposed on the upper surface conductive foil 104. It is believed that the aluminum foil 238 is responsible for carrying a majority of the electrical current in the photovoltaic module. Due to the decreased electrical conductivity of aluminum compared to copper, the thickness of the conductive foil 104 is generally greater than the thickness of a conductive foil formed purely from copper (e.g., about 50 microns). The increased thickness of the conductive foil 104 compared to a pure copper conductive foil compensates for the reduced electrical conductivity of aluminum.

The conductive foil 104, which includes multiple layers (e.g., aluminum foil 238 and the metal layer 240) formed from different metals, can be produced less expensively than a conductive foil formed entirely from copper. Copper is relatively more expensive than aluminum, thus, by forming a majority of the conductive foil 104 from aluminum, the cost of the conductive foil 104 can be reduced. The reduction in the cost of materials of the conductive foil 104 due to the use of aluminum foil 238 allows the manufacturing cost of the photovoltaic module 100 (shown in FIG. 1) to be reduced. Thus, the cost per kilowatt hour of energy produced by the photovoltaic module 100 is also reduced.

The metal layer 240 is positioned on the upper surface of the aluminum foil 238 to reduce the contact resistance with the conductive adhesive 120 or the anti-corrosion material 242 (when using silver ion immersion, as discussed below). The metal layer 240 reduces the contact resistance between the conductive foil 104 and the anti-corrosion material 242 or conductive adhesive 120 by covering the upper surface of the aluminum foil 238. By covering the upper surface of the aluminum foil 238, the metal layer 240 prevents oxidation of the aluminum foil 238. Aluminum oxide, which can be formed during photovoltaic manufacturing due to atmospheric exposure, has a greater electrical resistance than aluminum. Thus, if the anti-corrosion material 242 or the conductive adhesive 120 was disposed in contact with aluminum oxide, the photovoltaic module would experience increased contact resistance at the aluminum oxide interface, thus reducing device performance. However the application of the metal layer 240 prevents oxidation of the upper surface of the aluminum foil 238, resulting in the ability to use aluminum as the conductor.

Additionally, not only does the metal layer 240 reduce contact resistance in the photovoltaic module, but the metal layer 240 also improves adhesion of the solar cell 110 to the conductive foil 104. Metal pastes, such as the conductive adhesive 120, adhere poorly to aluminum, such as the aluminum foil 238. Poor adhesion of the conductive adhesive degrades the reliability of the photovoltaic module. However, by applying the metal layer 240 to the upper surface of the aluminum foil 238, a reliable bond can be formed between the conductive foil and the conductive adhesive 120. Thus, reliability of the photovoltaic module can be maintained even when using less expensive materials for the conductive foil 104, such as aluminum foil.

In order to prevent oxidation, tarnishing, or corrosion of the metal layer 240, an anti-corrosion material 242, such as an organic triazole (e.g., benzene triazole), is applied to the upper surface of the metal layer 240 of the conductive foil 104. The anti-corrosion material 242 is applied in a pattern defined by openings through the dielectric material 106, as well as onto any other exposed portions of the metal layer 240. It is generally not necessary to apply the anti-corrosion material 242 to the entire surface of the metal layer 240, since electrical connection to the conductive foil 104 by the conductive adhesive 120 will only be made in the areas defined by the openings through the dielectric material 106. However, it is contemplated that the anti-corrosion material 242 may be disposed on the entire surface of the conductive foil 104 in some embodiments.

It is to be noted that anti-corrosion material 242 may or may not form an actual physical layer on the upper surface of the conductive foil 104, for example, when using a liquid anti-corrosion material. However, for purposes of explanation, embodiments herein will be described as the conductive adhesive 120 in contact with the conductive foil 104 (except in embodiments using silver as an anti-corrosion material); although it is to be understood that a few angstroms of anti-corrosion material 242 may be present therebetween. The layer of anti-corrosion material 242 illustrated in FIG. 2 is meant only to represent the application of an anti-corrosion material, and is not intended to represent the presence of a physical layer in all circumstances.

In addition to organic triazoles, the use of other anti-corrosion materials is contemplated. For example, the anti-corrosion material 242 may be ENTEK® CU 56 available from Enthone, Inc. In an alternative embodiment, the anti-corrosion material 242 may be a metal layer, such as silver, tin or nickel, having a thickness of about 0.1 micrometer to about 1.5 micrometers. In an embodiment where a metal layer is used as the anti-corrosion material 242, the anti-corrosion material 242 would be a physical layer between the conductive adhesive 120 and the conductive foil 104. In one example, the anti-corrosion finish (ACF) material may be selected from one of the classes of desirable contact enhancing materials known as organic solderability preservative (OSP) materials or silver immersion finish materials. In another example, the ACF material comprises a silver immersion material, which comprises silver (Ag), that has a thickness between about 0.1 and about 1.5 μm, such as 0.4 μm over the surface of the conductive foil 104. In another example, the anti-corrosion material 242 comprises a silver containing layer that is formed by an electrochemical deposition process, electroless deposition process, physical vapor deposition (PVD) process, chemical vapor deposition (CVD) process or other similar deposition technique.

FIG. 3A is a top plan view of a conductive foil assembly 350 according to one embodiment of the invention. The conductive foil assembly 350 is an assembly which can be pre-assembled at a different location than the photovoltaic module assembly station, and applied to a photovoltaic module during the photovoltaic module assembly process. The conductive foil assembly 350 includes a conductive foil 104 having grooves 114 therein coupled to a carrier 252. The carrier 252 is formed from a polymeric material, such as PET, and has a thickness within a range from about 10 microns to about 125 microns. The carrier 252 is shaped similar to and has a width greater than the conductive foil 104. For example, the conductive foil 104 may have a width of about 16 centimeters, while the carrier may have a width of about 18 centimeters. The carrier 252 is adhered to the conductive foil 104 by an adhesive 254 (shown in FIG. 3B), such as a pressure sensitive adhesive, for example, FLEXMARK® PM 500 (clear) available from Flexcon of Spencer, Mass. Desirably, the adhesive 254 experiences low outgassing when positioned between the carrier 252 and the conductive foil 104. The carrier 252 shown in FIG. 3A is sized to accommodate three solar cells thereon.

FIG. 3B is a cross-sectional view of the conductive foil assembly 350 shown in FIG. 3A along section line 3B-3B. The conductive foil assembly 350 includes a dielectric material 106 disposed over the upper surface of the conductive foil 104. The dielectric material 106 has openings 118 formed therethrough. The openings 118 define a pattern in which an anti-corrosion material 242 is applied to the upper surface of the conductive foil 104. The anti-corrosion material 242 prevents formation of an oxide layer on the metal layer 240 which is located on the aluminum foil 238. Thus, the conductive foil assembly 350 includes many of the subcomponents of a photovoltaic module in a preassembled structure. Photovoltaic module assembly time is reduced by utilizing the preassembled subcomponents included in the conductive foil assembly 350, because the conductive foil assembly 350 can be positioned in a photovoltaic module in a single process step.

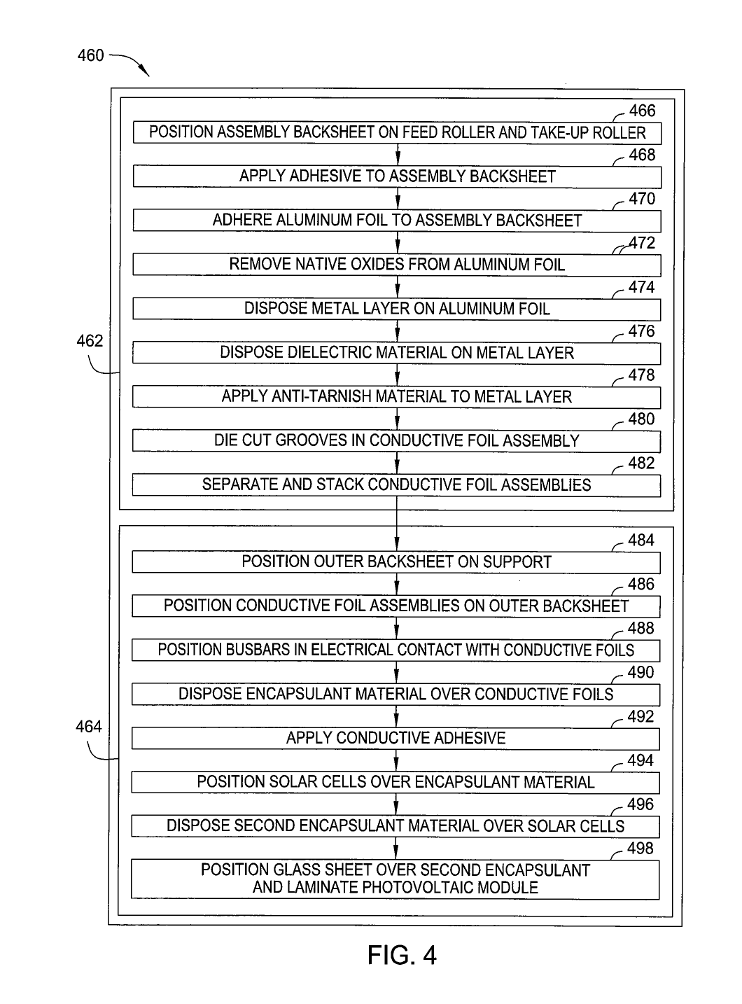

FIG. 4 is a flow diagram 460 illustrating a method for forming a photovoltaic module according to one embodiment of the invention. The flow diagram 460 is divided into steps 462 and 464. In step 462, one or more conductive foil assemblies are formed. In step 464, a photovoltaic module is assembled using the one or more conductive foil assemblies formed in step 462.

Step 462 generally occurs in a roll-to-roll process and is divided into a plurality of substeps. The substeps of step 462 are performed in a continuous roll-to-roll process. Step 462 begins with substep 466, in which a roll of a first carrier material is positioned on a feed roller and a take-up roll. The roll of first carrier material may have a length of about 100 meters. In substep 468, an adhesive, such as a pressure sensitive adhesive, is roll printed on the upper surface of the first carrier material in a predetermined pattern. The predetermined pattern corresponds to the shape of an aluminum foil to be subsequently adhered to the upper surface of the first carrier material. In substep 470, a sheet of aluminum foil is adhered to the first carrier material. The aluminum foil, which is stored on a feed roller, is unrolled and disposed on the adhesive located on the first carrier material. The first carrier material and the aluminum foil thereon are passed through a set of rollers adapted to apply sufficient pressure to the first carrier material and the aluminum foil to activate the pressure sensitive adhesive positioned therebetween. The activation of the pressure sensitive adhesive bonds the aluminum foil to the upper surface of the first carrier material.

In substep 472, after adhesion of the aluminum foil to the first carrier material, the aluminum foil and the first carrier material are positioned in a process chamber and exposed to a plasma formed from an inert gas, such as an argon plasma. The process chamber may have openings in the sides thereof to accommodate the roll of aluminum foil and carrier material passing therethrough as is known in web coating installations. The plasma is generated by a hollow anode or linear ion source. When utilizing a hollow anode, a roller positioned beneath the hollow anode and the aluminum foil is biased negatively with a direct current. When using a linear ion source, a beam energy of about 1000 eV is utilized. The plasma contacts the upper surface of the aluminum foil to etch and remove native oxides from the upper surface of the aluminum foil. Generally, the aluminum foil is not biased during the etching process. Therefore, the aluminum foil is not excessively etched to undesirably remove metallic aluminum foil. Rather, the plasma etch generally only removes the native oxides from the surface of the aluminum foil. The native oxides on the surface of the aluminum foil are undesirable due to decreased electrical conductivity of the native oxides, and the corresponding increased contact resistance of electrically conductive layers subsequently disposed on the upper surface of the aluminum foil. Therefore, to improve the performance of the final photovoltaic module, it is desirable to remove the native oxides from the aluminum foil.

In substep 474, after etching the surface of the aluminum foil and without exposing the aluminum foil to an oxygen containing ambient (to prevent formation of another native oxide layer), a metal layer, such as a copper layer, is applied to the upper surface of the aluminum foil. The metal layer is deposited on the aluminum foil in a sputtering chamber adapted to accommodate the roll of the first carrier material and aluminum foil passing through and positioned within a processing region of the sputtering chamber. The metal layer seals the surface of the aluminum foil and prevents the formation of a native oxide surface on the aluminum foil. Additionally, the metal layer provides a surface for increased bonding strength of a conductive adhesive subsequently applied thereto, since conductive adhesives generally bond poorly to aluminum foils (resulting in reliability issues in the final device). The metal layer is applied to the aluminum foil by sputtering material from a metal target to the surface of the aluminum foil using a non-reactive sputtering gas, such as argon. The thickness of the metal sputtered onto the surface of the aluminum foil generally varies depending on the metal being sputtered. For example, when sputtering copper onto the surface of the aluminum foil, the copper may be sputtered to a thickness within a range from about 500 angstroms to about 2500 angstroms.

During the sputtering process, the aluminum foil and the first carrier material are positioned within a processing chamber. A hollow anode or linear ion source is used to sputter a metal from a target onto the upper surface of the aluminum foil. A hollow anode or linear ion source is utilized rather than an RF source so that RF current is not undesirably coupled along the aluminum foil to other locations in the roll-to-roll processing system. Since the conductive foil assembly formed in step 462 is produced using a continuous roll-to-roll process, the aluminum foil and the first carrier material pass through a plurality of processing stations, both upstream and downstream of the sputtering chamber, during processing. Coupling RF current along the aluminum foil to the upstream or downstream processing locations could result in dangerous processing conditions by providing RF current to undesired locations. Thus, it is desirable to provide a sufficient RF current return path in the sputtering chamber to avoid coupling RF current to undesired locations in the roll-to-roll processing system.

After forming a metal layer on the upper surface of the aluminum foil, in substep 476, a dielectric material is printed on the upper surface of the metal layer disposed on the aluminum foil. The dielectric material is applied by screen printing or roll coating to substantially the entire surface of the aluminum foil in a pattern having openings therethrough. If the dielectric material requires curing, the dielectric material is cured after being applied to the upper surface of the metal layer. Suitable curing processes generally depend on the composition of the dielectric material, and may include ultraviolet or thermal curing, among other curing processes. Subsequent to disposing the dielectric material on the metal layer, the carrier is moved downstream, the dielectric material is positioned adjacent to a screen printing device adapted to apply an anti-corrosion material. In substep 478, an anti-corrosion material is applied to the exposed portions of the metal layer including a pattern defined by the openings through the dielectric material. The anti-corrosion material is a liquid material which prevents corrosion, tarnishing, or oxidation of the exposed portions of the metal layer. The anti-corrosion material is applied by disposing the aluminum foil and the layers thereon into a bath of the anti-corrosion material during the roll-to-roll process. A series of rollers are positioned in order to guide the aluminum foil and the layers thereon through the bath.

In substep 480, after application of the anti-corrosion material, the first carrier material having the aluminum foil, the metal layer, the dielectric material and the anti-corrosion material thereon is positioned adjacent to a die set in a punch press. The punch press is actuated by an actuator and the die set forms a plurality of grooves through the dielectric layer, the metal layer, and the aluminum foil. Preferably, the punch press is adjusted so that the die set does not cut through the first carrier material. Since the first carrier material is not cut by the die set, the discrete sections of conductive foil (separated by the grooves formed by the die set) remain supported on a uniform piece of first carrier material, rather than being cut into individual sections.

In substep 482, the roll of first carrier material and grooved conductive foil thereon are cut into sections of predetermined lengths using a blade, forming a plurality of conductive foil assemblies. The length of the conductive foil assemblies can be chosen based on the number solar cells desired to be positioned thereon. For example, the length of the conductive foil assemblies may be selected to accommodate about ten solar cells thereon. The conductive foil assemblies are then picked up with a robot and stacked in a storage unit, such as a magazine, for use in the formation of a photovoltaic module.

One benefit of sectioning the roll in substep 482 is that sections can be cut into multiple lengths. This is especially advantageous when forming photovoltaic modules of different sizes, or when forming photovoltaic modules which include multiple conductive foils of different lengths. Photovoltaic modules may include conductive foils of different lengths, for example, to facilitate connection with busing ribbons positioned on the photovoltaic module. In one example, a photovoltaic module has conductive foils on the outer edge thereof which are spaced farther apart from respective busing ribbons as compared to conductive foils located interior to the outer conductive foils. In such an example, it would be desirable that the length of the conductive foils near the outer edge of the photovoltaic module would have a length greater than the interior conductive foils to facilitate contact with the busing ribbons positioned adjacent thereto.

Step 464 is divided into a plurality of substeps for forming a photovoltaic module using the conductive foil assemblies formed in step 462. In substep for 484 of step 464, a second carrier material sized to accommodate a predetermined number of solar cells is positioned on a support. The support includes a plurality of openings formed in the surface thereof through which vacuum suction may be applied to assist in maintaining the second carrier material in a desired position. In substep 486, one or more conductive foil assemblies are positioned on the second carrier material. The conductive foil assemblies are positioned on the second carrier material in a predetermined pattern using a robot. The robot picks up a conductive foil assembly from the magazine of conductive foil assemblies, while simultaneously an adhesive is applied, for example by roller application or screen printing, onto the upper surface of the second carrier material. The robot then disposes the second carrier material of the conductive foil assembly on the screen printed adhesive. If multiple conductive foils are to be applied to the upper surface of the second carrier material, substep 486 is then repeated.

Subsequent to placement of the conductive foils on the second carrier material, busbars are positioned over the second carrier material in electrical contact with each of the conductive foils in substep 488. The busbars are placed on the second carrier material using a robot and then an electrically conductive adhesive is applied to each of the conductive foils to form an electrical connection. Additionally, an opening is formed through second carrier material adjacent to the busbars so that the busbars may be disposed therethrough to allow for an electrical connection from the front surface of the photovoltaic module to the back surface. In substep 490, after placement of the busbars, a sheet of encapsulant material is positioned over the dielectric material disposed on the conductive foils using a robot. The sheet of encapsulant material includes openings therethrough which are aligned with the openings through the dielectric material.

In substep 492, a conductive adhesive is screen printed over the conductive foils in the openings of the dielectric material and the encapsulant. The conductive adhesive forms an electrical connection between the conductive foils and the back contacts of the solar cells subsequently positioned thereon. In substep 494, a plurality of solar cells are positioned over the sheet of encapsulant and in electrical contact with the conductive adhesive. The solar cells are positioned on the encapsulant material using a robot having vacuum grippers. The robot picks up a solar cell from a stack of solar cells, and places the solar cell in predetermined location on the photovoltaic module. The process is repeated until the desired number of solar cells have been positioned on the photovoltaic module.

In substep 496, a second layer of encapsulant is positioned over the solar cells in the photovoltaic module. The second layer is a sheet of encapsulant and is positioned using a robot. The second layer of encapsulant may be formed from a similar material as the first layer of encapsulant, and covers substantially the entire photovoltaic module. The second layer of encapsulant prevents the formation of undesired pockets of air in the photovoltaic module, as well as provides separation and coefficient of thermal expansion compliance between the solar cells and a glass sheet subsequently placed thereover. In substep 498, a transparent glass sheet is positioned over the second layer of encapsulant by a robot. The photovoltaic module is then subjected to heat, for example about 155° C., while pressure is applied to the upper surface of the glass sheet to laminate the photovoltaic module.

Flow diagram 460 illustrates one embodiment of forming a photovoltaic module; however, other embodiments of forming photovoltaic modules are contemplated. In another embodiment, the substeps of step 462 and 464 do not occur in a continuous roll-to-roll process. Rather, substeps 466-470 occur in a first process location; substeps 472-474 occur in a second process location; substeps 476-482 occur in a third process location; substeps 484-486 occur in a fourth process location, and substeps 488-498 occur in a fifth process location. In such an embodiment, the carrier roll (and the layers thereon) are positioned on a new feed roller/take-up roller, or support, in each process location. Further, in such an embodiment, openings through the carrier to accommodate busbars may be formed at the fourth process location subsequent to substep 486. In yet another embodiment, it is contemplated that steps 462 and 464 may be peformed in a planar process, e.g., performed without the use of feed rollers and take-up rollers.

In another embodiment, substep 468 includes screen printing or spraying an adhesive to the upper surface of the carrier. In another embodiment, it is contemplated that each of substeps 466-482 occurs in a vacuum enclosure without breaking vacuum between substeps. In another embodiment, the plasma used to remove native oxides from the surface of the aluminum foil in substep 472 may be formed from gases other than argon, including neon and xenon. The gas used to form the plasma need not be a noble gas, but rather, any gas which is chemically inert with respect to the aluminum foil can be used. Furthermore, it is contemplated that the plasma may also include hydrogen. In yet another embodiment, the metal layer applied in substep 474 may be alternatively applied by chemical vapor deposition, atomic layer deposition, electroless deposition, electrochemical plating or molecular beam epitaxy. Additionally, the metal layer deposited in substep 474 may be one or more layers of gold, tin, silver, platinum, titanium, nickel, vanadium, chromium, aluminum, or copper. For example, a discrete layer of nickel or a nickel-vanadium alloy may be disposed between the aluminum foil and a layer of copper to increase adhesion of the copper to the aluminum foil, or to increase solderability thereto when used for interconnection. The adhesion layer generally has thickness within a range from about 10 nanometers to about 100 nanometers.

In another embodiment, the dielectric material applied in substep 476 may be disposed on the upper surface of the metal layer by rubber stamping or roll coating. In yet another embodiment, it is contemplated that the anti-corrosion material applied during substep 478 may also be applied by roll coating rather than dip coating in a bath. Alternatively, it is contemplated that the anti-corrosion material may be a metal, such as silver, which may be applied by silver immersion or sonic welding. In another embodiment, it is contemplated that the conductive foils may be soldered to the busbars in substep 488, especially when nickel is used an interlayer between the aluminum foil and the metal layer disposed thereon. In yet another embodiment, it is contemplated that the encapsulant material positioned in the photovoltaic module in substeps 490 and 496 may be screen printed or roll coated over the dielectric material. Additionally, it is contemplated that the sheet of encapsulant material positioned in substep 490 may lack openings therethrough when being positioned in the photovoltaic module. In such an embodiment, a laser may be used to subsequently form openings through the sheet of encapsulant material while the encapsulant material is disposed over the dielectric material.

In another embodiment, it is contemplated that that a plasma generated using RF power may be utilized in substeps 472 and 474. In such an embodiment, either substep 480 occurs prior to substep 474, or the aluminum foil is separated into sheets of desired length prior to substep 474. In such an embodiment, the likelihood of coupling RF current to undesired locations in the roll-to-roll process system (e.g., upstream or downstream of the sputtering chamber) is reduced since the aluminum foil is a discontinuous film (either as result of the grooves formed therein or the separation of the aluminum foil into individual pieces). However, it is contemplated that the sputtering may bridge or deposit over the grooves when substep 480 occurs prior to substep 474, thus connecting discrete portions of the aluminum foil. If the grooves are bridged by the sputtering metal, it is contemplated that substep 480 may be performed a second time subsequent to substep 474. In yet another embodiment, it is contemplated that substep 480 occurs subsequent to substep 474 but prior to substep 476. In such an embodiment, the dielectric material may be disposed within the grooves formed by the punch press.

In another embodiment, substep 472 may be accomplished by chemical etching removal of the native aluminum oxide from the aluminum surface and the deposition of a protective layer of zinc metal as for example in a zincate process. This coating is immediately followed by substep 474, by the electroplating of a metal layer on the aluminum substrate. The plated metal forms a good metallurgical bond without the presence of oxides at the interface. The plated metal may be copper of a thickness of 0.25 to 2.5 micron, preferably 1 micron, using for example a cyanide containing bath copper electroplating process. Alternatively, other metals such as nickel (Ni) or tin (Sn) may be applied prior to the copper deposition. The oxide removal and plating processes can be conducted in a vertical or horizontal format. The process is preferably conducted in a continuous roll-to-roll format, but may be alternatively performed on individual sheets of material.

Although embodiments herein generally describe the formation of photovoltaic modules using 1145 aluminum foil, other compositions of aluminum are contemplated. For instance, alloys with copper or other metals may be used to minimize electromigration in the structure during current flow in operation. Additionally, it is contemplated that adhesives other than pressure sensitive adhesives may be utilized. For example, it is contemplated that temperature-curable adhesives, or temperature-curing adhesives under pressure, or ultraviolet-curable adhesives may be utilized. Furthermore, while embodiments herein generally describe conductive foils for use in photovoltaic modules, it is contemplated that the conductive foils described herein may have uses in addition to photovoltaics. For example, it is contemplated that the conductive foils described herein may be utilized in flexible circuit applications or battery applications, as well as in other electronic applications.

Benefits of the present invention include reduced manufacturing costs for photovoltaic modules. Conductive foils for the photovoltaic modules are manufactured less expensively due to the use of aluminum foil, which is a cheaper alternative to copper. The conductive foils have reduced contact resistance and increased bonding affinity to conductive adhesives due to a copper coating applied to the upper surface of the aluminum foil. The conductive foils also reduce photovoltaic module assembly time, since the conductive foils can be formed on a conductive foil assembly prior to photovoltaic module construction. The conductive foil assemblies can be stored in a magazine, and integrated into the photovoltaic module in a single process step.

While the foregoing is directed to embodiments of the present invention, other and further embodiments of the invention may be devised without departing from the basic scope thereof, and the scope thereof is determined by the claims that follow.

We claim:

1. A substrate for interconnecting photovoltaic devices, comprising:
a first carrier comprising a first polymeric material;
a second carrier comprising a second polymeric material;
a first adhesive disposed between the first carrier and the second carrier;
a second adhesive disposed on one surface of the second carrier; and
a conductive foil disposed on the second adhesive, the conductive foil comprising:
an aluminum foil in contact with the adhesive; and
a first metal layer disposed over the aluminum foil.

2. The substrate of claim 1, wherein the conductive foil further comprises a plurality of columnar strips that are electrically isolated from each other by a gap, and each columnar strip comprises a plurality of conductive regions that are separated by a groove.

3. The substrate of claim 2, wherein the plurality of columnar strips each have a length, and the magnitude of the length of at least two of the plurality of columnar strips are different.

4. The substrate of claim 2, further comprising a plurality of busbars, wherein at least one of the plurality of busbars are electrically coupled to at least one of the columnar strips.

5. The substrate of claim 1, wherein the conductive foil comprises a plurality of conductive regions that are each electrically separated from an adjacent conductive region by a non-straight groove.

6. The substrate of claim 1, wherein the conductive foil further comprises an anti-corrosion material disposed on the first metal layer.

7. The substrate of claim 6, wherein the anti-corrosion material comprises an organic triazole.

8. The substrate of claim 6, wherein the first metal layer comprises copper, and the anti-corrosion material comprises a second metal layer comprising tin (Sn), silver (Ag) and nickel (Ni).

9. The substrate of claim 6, further comprising a dielectric material having openings therethrough disposed on the first metal layer, wherein the anti-corrosion material is disposed on first metal layer in areas of the first metal layer defined by the openings through the dielectric material.

10. The substrate of claim 1, wherein the second polymeric material comprises polyester.

11. The substrate of claim 1, wherein the conductive foil further comprises a second metal layer disposed between the first metal layer and the aluminum foil, wherein the second metal layer comprises nickel, vanadium, titanium, chromium or combinations thereof.

12. The substrate of claim 1, wherein the first metal layer comprises tin, silver, gold, platinum, titanium, copper, nickel, vanadium, chromium or combinations thereof.

13. The substrate of claim 1, wherein the first carrier layer comprises a material selected from a group consisting of polyethylene terephthalate (PET), polyvinyl fluoride (PVF), polyester, polyethelene naphthalate, MYLAR, KAPTON, TEDLAR and polyethylene.

14. The substrate of claim 1, further comprising an encapsulant material layer disposed over the conductive foil that comprises ethylene-vinyl acetate (EVA).

15. A substrate for interconnecting photovoltaic devices, comprising:
a first carrier comprising a first polymeric material;
a second carrier comprising a second polymeric material;
a first adhesive disposed between the first carrier and the second carrier;
a second adhesive disposed on one surface of the second carrier; and
a conductive foil disposed on the second adhesive and forms part of an electrical circuit used to interconnect two or more back contact solar cells, the conductive foil comprising:
an aluminum foil in contact with the adhesive; and
a first metal layer disposed over the aluminum foil.

16. The substrate of claim 15, wherein the conductive foil further comprises a plurality of columnar strips that are electrically isolated from each other by a gap, wherein the plurality of columnar strips each have a length, and the magnitude of the length of at least two of the plurality of columnar strips are different.

17. The substrate of claim 15, wherein the conductive foil further comprises a plurality of conductive regions that are each electrically separated from an adjacent conductive region by a non-straight groove.

18. The substrate of claim 17, further comprising a plurality of busbars, wherein at least one of the busbars are electrically coupled to at least one of the plurality of conductive regions.

19. The substrate of claim 15, wherein the conductive foil further comprises an anti-corrosion material disposed on the first metal layer.

20. The substrate of claim 19, wherein the first metal layer comprises copper, and the anti-corrosion material comprises a second metal layer comprising tin (Sn), silver (Ag) or nickel (Ni).

21. The substrate of claim 15, wherein the first metal layer comprises tin, silver, gold, platinum, titanium, copper, nickel, vanadium, chromium or combinations thereof.

22. A substrate for interconnecting photovoltaic devices, comprising:
a first carrier comprising a first polymeric material;
a second carrier comprising a second polymeric material;
a first adhesive disposed between the first carrier and the second carrier;
a second adhesive disposed on one surface of the second carrier; and
a conductive foil disposed on the second adhesive and forms part of an electrical circuit used to interconnect two or more back contact solar cells, the conductive foil comprising:
an aluminum foil in contact with the adhesive, wherein the aluminum foil comprises a plurality of conductive regions that are each electrically separated from an adjacent conductive region by a non-straight groove; and
a copper layer disposed over at least a portion the plurality of conductive regions.

23. The substrate of claim 22, wherein the conductive foil further comprises a plurality of columnar strips that are electrically isolated from each other by a gap, wherein the plurality of columnar strips each have a length, and the magnitude of the length of at least two of the plurality of columnar strips are different.

24. The substrate of claim 22, wherein the conductive foil further comprises an anti-corrosion material disposed on the copper layer, and wherein the anti-corrosion material further comprises a metal layer comprising tin (Sn), silver (Ag) or nickel (Ni).

25. The substrate of claim 22, wherein the first carrier layer comprises a material selected from a group consisting of polyethylene terephthalate (PET), polyvinyl fluoride (PVF), polyester, polyethelene naphthalate, MYLAR, KAPTON, TEDLAR and polyethylene.

26. A method of forming a conductive foil assembly, comprising:
adhering an aluminum foil to a carrier;
positioning the aluminum foil and the carrier in a chamber, the aluminum foil and the carrier supported on a feed roller and a take-up roller;
exposing a surface of the aluminum foil to an ionized gas to remove native oxides therefrom;
forming a metal layer over the surface of the aluminum foil;
applying a dielectric material to a surface of the formed metal, the dielectric material having openings therethrough; and
applying an anti-corrosion material to the formed metal layer in the areas defined by the openings through the dielectric material.

27. The method of claim 26, further comprising forming a plurality of grooves in the aluminum foil and the formed metal layer.

28. The method of claim 26, wherein the formed metal layer comprises copper.

29. The method of claim 26, wherein forming the metal layer comprises sputtering a metal selected from a group consisting of gold, tin, copper, silver and titanium.
